(19) United States
(12) Patent Application Publication
(10) Pub. No.: US 2025/0188613 A1
(43) Pub. Date: Jun. 12, 2025

(54) HEAT SHEILD MEMBER AND SUBSTRATE PROCESSING APPARATUS

(71) Applicant: TOKYO ELECTRON LIMITED, Tokyo (JP)

(72) Inventor: Atsushi SHIROTA, Yamanashi (JP)

(21) Appl. No.: 18/969,230

(22) Filed: Dec. 4, 2024

(30) Foreign Application Priority Data
Dec. 12, 2023 (JP) 2023-209505

(51) Int. Cl. C23C 16/458; B33Y 80/00; F16L 59/02

(52) U.S. Cl. CPC C23C 16/4585; F16L 59/029; B33Y 80/00

(57) ABSTRACT

A heat shield member for shielding heat includes: a spiral portion formed by spirally winding a plate-like body to have a surface of the plate-like body overlapped at intervals in multiple layers.

### CROSS-REFERENCE TO RELATED APPLICATION

This application is based upon and claims the benefit of priority from Japanese Patent Application No. 2023-209505, filed on Dec. 12, 2023, the entire contents of which are incorporated herein by reference.

### TECHNICAL FIELD

The present disclosure relates to a heat shield member and a substrate processing apparatus.

### BACKGROUND

Patent Document 1 discloses a substrate processing apparatus in which a heat shield for shielding a shower head from heat is provided outside a wafer placement region of a stage, which is heated by a lamp and configured to place a substrate thereon, and discloses a stacked structure as the heat shield. Patent Document 2 discloses a single-crystal manufacturing apparatus for epitaxially growing a single crystal on a substrate by a chemical vapor deposition (CVD) method, in which a heat insulating material is provided on a placement surface on which a substrate is placed, and heating of the substrate due to thermal conduction from a susceptor to the substrate is suppressed, and discloses that the heat insulating material may have a stacked structure.

### PRIOR ART DOCUMENTS

### Patent Documents

Patent Document 1: Publication of JP Patent No. 5068471
Patent Document 2: Publication of JP Patent No. 5805115

### SUMMARY

According to one embodiment of the present disclosure, there is provided a heat shield member for shielding heat, the heat shield member including: a spiral portion formed by spirally winding a plate-like body to have a surface of the plate-like body overlapped at intervals in multiple layers.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a perspective view showing an example of a heat shield member according to an embodiment.

FIG. 2 is a cross-sectional view of the heat shield member according to the embodiment.

FIG. 3 is a perspective view schematically showing a spiral portion included in the heat shield member according to the embodiment.

FIG. 4 is a cross-sectional view showing a conventional heat shield member.

FIG. 5 is a cross-sectional view showing a substrate processing apparatus to which the heat shield member of the embodiment is applied.

FIG. 6 is a diagram for illustrating a model used in a simulation showing an effect of the heat shield member of the embodiment.

FIG. 7 is a diagram for illustrating a model of Case 1, which is a heat shield member of a conventional structure.

FIG. 8 is a diagram for illustrating a model of Case 2, which is the heat shield member of a structure of the embodiment.

FIG. 9 is a diagram showing a simulation result of Case 1.

FIG. 10 is a diagram showing a simulation result of Case 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Heat Shield Member>

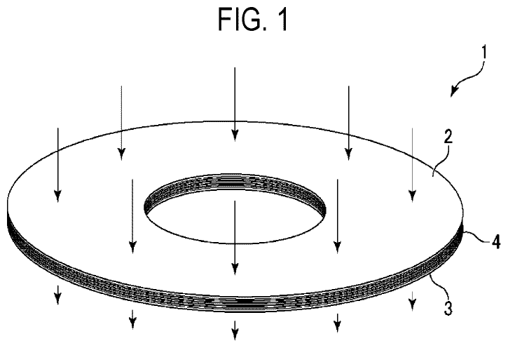

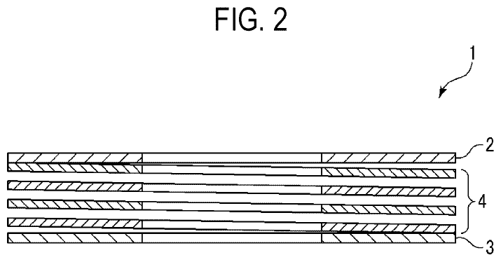

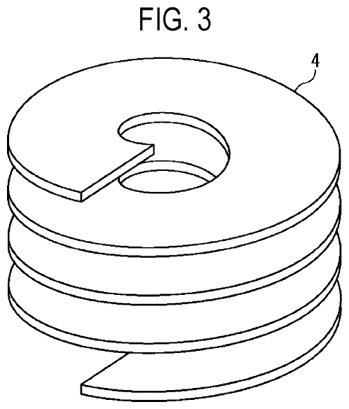

FIG. 1 is a perspective view showing an example of a heat shield member according to an embodiment, FIG. 2 is a cross-sectional view of the heat shield member, and FIG. 3 is a perspective view schematically showing a spiral portion included in the heat shield member according to the embodiment.

A heat shield member 1 of the embodiment serves to shield (insulate) heat. As shown in FIG. 1, an overall shape of the heat shield member 1 is annular. The heat shield member 1 includes a first flat plate 2 and a second flat plate 3 that form an annular shape and a spiral portion 4, and the spiral portion 4 is sandwiched between the first flat plate 2 and the second flat plate 3. Overall diameter and thickness of the heat shield member 1 are appropriately set depending on size and temperature of a heat generation source to be shielded, temperature to be reduced, and the like.

The first flat plate 2 and the second flat plate 3 may be formed of metal materials with low emissivity to reduce an amount of heat radiation. The metal material may be appropriately selected according to temperature or environment, and nickel (Ni) or an Ni alloy having high heat resistance and high corrosion resistance may be suitably used. Aluminum (Al), an Al alloy, or stainless steel is also usable depending on the temperature and environment. When the temperature employed is 700 degree C. or higher, a ceramic such as zirconia (ZrO₂), which has high emissivity but has heat resistance or corrosion resistance higher than that of Ni or Ni alloys, is appropriate. A thickness of each of the first flat plate 2 and the second flat plate 3 may be 1 to 3 mm.

As shown in FIG. 3, the spiral portion 4 is formed by spirally winding a plate-like body so that a surface of the plate-like body is overlapped at intervals in multiple layers. The spiral portion 4 functions as a main element for heat shield. Like the first flat plate 2 and the second flat plate 3, the spiral portion 4 may be formed of a metal material with low emissivity to reduce the amount of heat radiation. As the metal material, Ni or an Ni alloy, which has high heat resistance and high corrosion resistance, may appropriately be used but, depending on the temperature and environment, Al, an Al alloy, or stainless steel may also be used. The metal material may also be a composite of multiple metal materials. In addition to the metal material, the spiral portion 4 may be a ceramic, such as ZrO₂, or a composite of metal and ceramic, for example, a composite of Ni and ZrO₂. The spiral portion 4 may be appropriately selected from the above materials depending on the temperature and environment employed.

When the heat shield member 1 is used to shield radiant heat generated from a high-temperature member, it is advantageous for the entire heat shield member 1 to be formed of a metal material with low emissivity, and Ni or an Ni alloy, which has good heat resistance and good corrosion resistance, is particularly advantageous.

Although a thickness and a winding pitch of the plate-like body constituting the spiral portion 4 are arbitrary, the thickness of the plate-like body may be 1 to 3 mm and the pitch of the plate-like body may be 3 to 9 mm.

The spiral portion 4 may be a body produced by additive manufacturing. By using additive manufacturing, it is possible to manufacture the spiral portion 4 more easily than by processing the spiral portion 4 from a plate material. In addition, by using additive manufacturing, it is possible to easily manufacture a composite body of metal and ceramic. For additive manufacturing, raw data of thinly sliced pieces of a product is created based on digital data such as three-dimensional (3D) CAD of the product, and thin layers of desired materials are sequentially stacked based on the raw data. A 3D printer is typically used for additive manufacturing. As an additive manufacturing method, for example, a method in which a material powder supplied is melted with laser to form thin layers and the thin layers are sequentially stacked may be used.

Usage of the heat shield member 1 is not particularly limited but may be used, for example, in a substrate processing apparatus, such as a film forming apparatus, to shield (insulate) radiant heat generated from a high-temperature portion in a chamber maintained in a vacuum atmosphere. Specifically, in a single-wafer film forming apparatus or a batch-type film forming apparatus, the heat shield member 1 is used to shield radiant heat generated from a high-temperature heating type stage on which a substrate is placed. FIG. 1 shows an example of shielding radiant heat generated from an upper portion. Such a heat shield member 1 has a high heat shielding property and is capable of significantly increasing an amount of temperature drop (temperature gradient) on an opposite side with respect to a temperature on an input side of radiant heat.

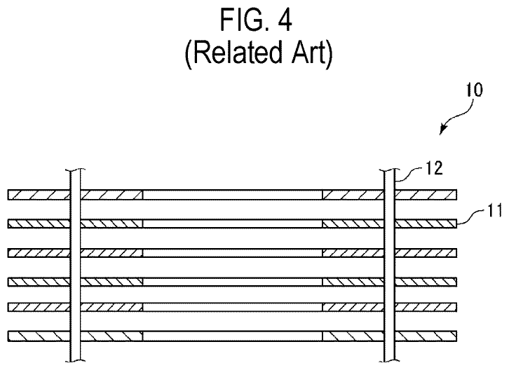

The heat shield member itself has been known conventionally, as disclosed in Patent Documents 1 and 2, and is also used to shield radiant heat in the film forming apparatus. However, in such a film forming apparatus, the substrate is heated to several hundred degrees and, in the case of a batch type, to a high temperature of 1,000 degrees C. or more, such that thermal energy of radiant heat is high. For this reason, a method has been used conventionally to gradually attenuate radiant heat by using a heat shield member 10 having a structure in which multiple heat shield plates 11 are stacked, as shown in FIG. 4. However, in this invention, it is essential to support the multiple heat shield plates 11 by a support 12, and heat transfer (thermal conduction) occurs among the heat shield plates 11 through the support 12, thereby reducing a heat shielding effect. For this reason, in order to obtain a desired heat shield effect by the conventional heat shield member 10, measures such as increasing the number of heat shield plates 11 are required, resulting in disadvantages such as increased material costs. In addition, since heat is conducted from the support 12, the vicinity of the support 12 becomes a cold spot. Thereby, when the conventional heat shield member 10 is placed under a high-temperature heating type stage, there is a concern that heat uniformity of the stage may deteriorate due to the influence of the cold spot.

In contrast, since the heat shield member 1 of the embodiment includes the spiral portion 4 formed by spirally winding the plate-like body to have the surface of the plate-like body overlapped at intervals in multiple layers, no support is required. Thereby, there is no thermal conduction through the support, and heat transfer between the layers of the spiral portion 4 is limited to radiant heat transfer. Strictly speaking, while heat is transferred to a lower layer in a spiral shape through the plate-like body constituting the spiral portion 4, a heat transfer distance is longer than when there is a support. For this reason, according to Fourier's law expressed by Equation (1) below, a decrease in a heat gradient (temperature gradient) ΔT due to thermal conduction may be suppressed (the heat gradient ΔT may be increased) compared to the case in which there is a support. In other words, by using the spiral portion 4, a decrease in a heat shielding effect caused by thermal conduction may be suppressed compared to the case in which there is a support.

$$q = - k ( Δ T / x ) \qquad ( 1 )$$

where q is heat flux, k is thermal conductivity, and x is heat transfer distance

In addition, by using the spiral portion 4, there are connecting portions between the layers, so a heat shield area is larger than in a structure in which the heat shield plates overlap, and the heat shield effect may be increased accordingly.

As described above, the heat shield member 1 of the embodiment has a greater heat shield effect than the structure in which the multiple heat shield plates overlap, so the thickness of the heat shield member 1 may be made smaller than conventional structures, and space may be saved. In addition, since the heat shield member 1 of the embodiment does not have any supports, there is no problem in temperature uniformity caused by the cold spot.

### <Application Example of Heat Shield Member>

Next, an application example of the heat shield member of one embodiment is described.

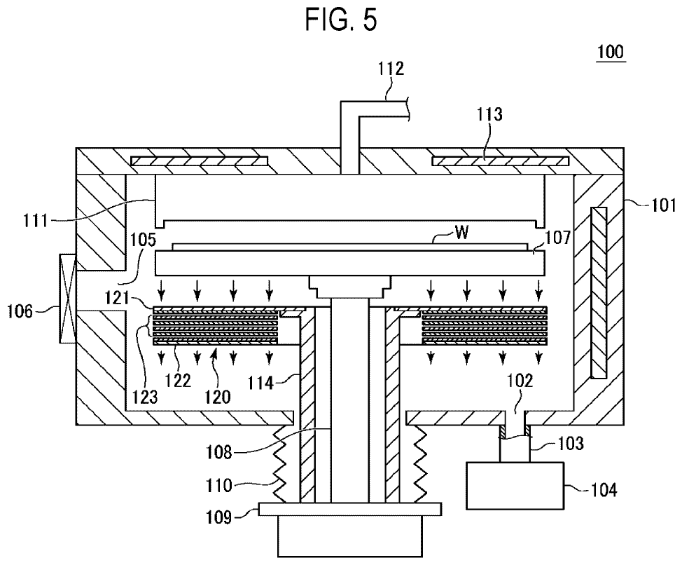

FIG. 5 is a cross-sectional view showing a substrate processing apparatus to which the heat shield member of the embodiment is applied. As shown in FIG. 5, a substrate processing apparatus 100 performs, for example, a film formation process on a substrate W and includes a substantially cylindrical metallic chamber (processing container) 101.

An exhaust port 102 is formed at a bottom wall of the chamber 101, and an exhaust pipe 103 is connected to the exhaust port 102. An exhauster 104 including a vacuum pump or a pressure regulating valve is connected to the exhaust pipe 103. By operating the exhauster 104, it is possible to create a predetermined reduced pressure (vacuum) state inside the chamber 101. An opening 105 for loading and unloading the substrate is formed at a side wall of the chamber 101, and a gate valve 106 for opening and closing the opening 105 is provided.

A high-temperature heating type stage 107 on which the substrate W is placed to heat the substrate W is horizontally provided inside the chamber 101. The stage 107 is formed of, for example, a ceramic, and a heater (not shown) is embedded therein. The stage 107 is heated to a high temperature, for example, about 400 to 700 degrees C., by the heater, and the substrate W is heated by the heat.

The stage 107 is attached and fixed to an upper end of a vertically extending metallic support 108. The support 108 extends downward by penetrating a bottom of the chamber 101 and is supported on a base 109. The stage 107 is configured to be raised and lowered between a transfer position corresponding to the opening 105 and a processing position above the transfer position through the support 108 by an actuator (not shown). A metallic bellows 110 that is expandable and contractible is provided at a penetration portion through which the support 108 penetrates the bottom of the chamber 101, thereby enabling the stage 107 to be raised and lowered while maintaining airtightness inside the chamber 101.

A shower head 111 is provided at an upper portion of the chamber 101 so as to face the stage 107. A gas supply pipe 112 extending from a gas supply (not shown) is connected to the shower head 111, and gases supplied from the gas supply through the gas supply pipe 112 to the shower head 111 are introduced into the chamber 101 in a shower form from the shower head 111. The gases used are process gases, such as a source gas or a reaction gas required for film formation, and a purge gas, etc. By supplying the process gases from the shower head 111, film formation is performed on the substrate W by atomic layer deposition (ALD), CVD, or the like.

A heater 113 is provided at the side wall and a ceiling wall of the chamber 101 to perform heating so that the source gas supplied into the chamber 101 does not liquefy or solidify.

A heat shield member 120, the overall shape of which is annular, is provided directly below the stage 107 in the chamber 101. The heat shield member 120, like the heat shield member 1 described above, includes a first flat plate 121 and a second flat plate 122 that form an annular shape, and a spiral portion 123, and the spiral portion 123 is sandwiched between the upper first flat plate 121 and the lower second flat plate 122. The heat shield member 120 is supported by attaching the first flat plate 121 to a support jig 114 that extends upward from the base 109.

When the substrate processing apparatus 100 performs, for example, a film formation process on the substrate W, the first flat plate 121, the second flat plate 122 and the spiral portion 123 of the heat shield member 120 are appropriately formed of materials with low emissivity and with heat resistance and corrosion resistance, such as Ni or Ni alloys.

In the substrate processing apparatus 100 configured in this way, the substrate W transferred into the chamber 101 is placed on the high-temperature heating type stage 107, which has been set to a predetermined temperature, for example, in a range of 400 to 700 degrees C. Then, the inside of the chamber 101 is exhausted and set to a desired vacuum pressure. Following, the process gases, such as the source gas or the reaction gas, are supplied sequentially or simultaneously from the shower head to form a desired film on the substrate W.

In this case, since the stage 107 is in a high temperature state, the heat shield member 120 shields radiant heat generated from the stage 107 so as to prevent the radiant heat from affecting a portion below the stage 107. Specifically, the radiant heat of the stage 107 is gradually attenuated by the first flat plate 121, multiple layers of the spiral portion 123, and the second flat plate 122. Thereby, energy of the radiant heat from the stage 107 is reduced and a temperature of an outlet side of the heat shield member 120 may be sufficiently lowered relative to a temperature of an inlet side of the heat shield member 120.

### <Simulation Results>

Next, simulation results showing an effect of the heat shield member according to one embodiment is described.

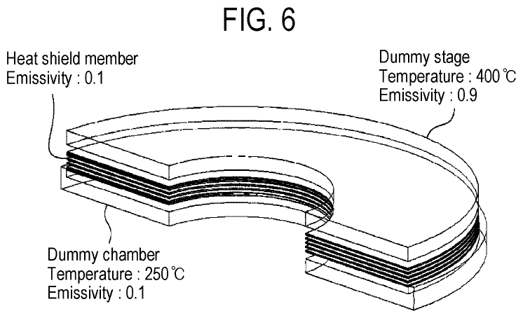

Herein, as shown in FIG. 6, a simulation is performed using a model in which an annular heat shield member with an emissivity of 0.1 (simulating Ni) is placed between a dummy stage with a temperature of 400 degrees C. and an emissivity of 0.9 and a dummy chamber with a temperature of 250 degrees C. and an emissivity of 0.1.

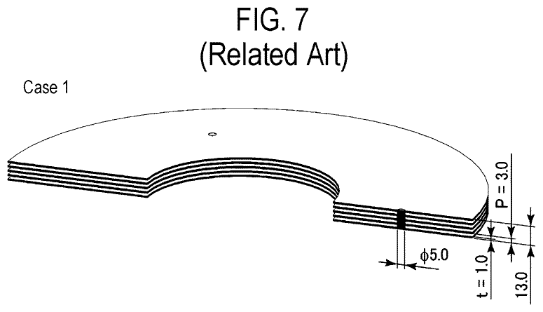

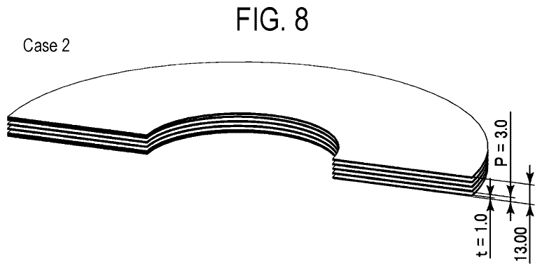

As models of the heat shield member, Case 1 with a conventional structure and Case 2 with the structure of the above embodiment are used. As shown in FIG. 7, Case 1 has five overlapping 1-mm plates at a pitch of 3 mm, supported by three metallic support columns with p 5 mm, so that an overall thickness is 13 mm. As shown in FIG. 8, Case 2 has a spiral portion of a 1-mm thick plate spirally wound at a pitch of 3 mm, sandwiched between 1-mm thick plates, so that an overall thickness is the same at 13 mm as that of Case 1.

The simulation is performed under an assumption that there is no convection effect, that an environment is vacuum (0 Pa), and that there is no thermal conduction between the plates.

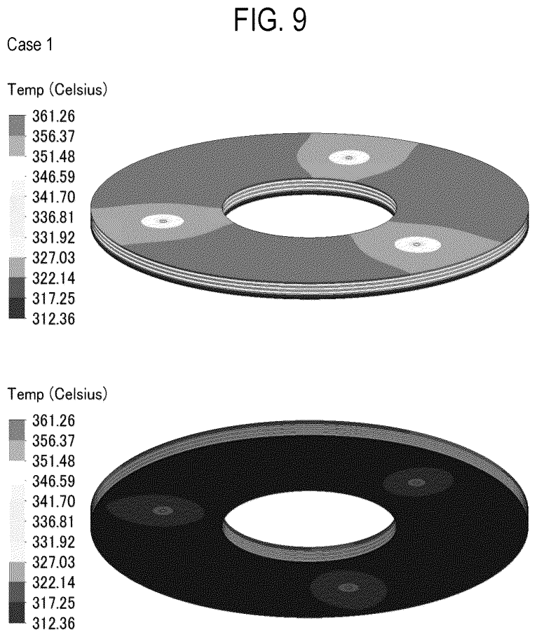

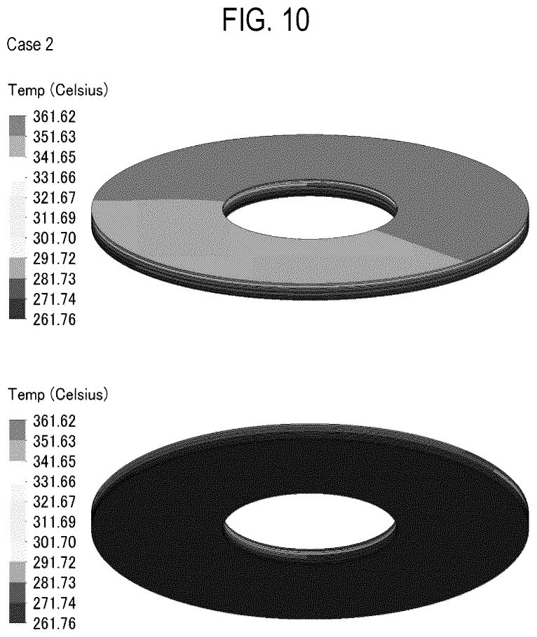

Simulation results for Case 1 and Case 2 are shown in FIGS. 9 and 10, respectively. As shown in FIG. 9, in Case 1, a temperature of an upper surface is 361.26 degrees C., a temperature of a lower surface is 312.36 degrees C., and ΔT is 49 degrees C., whereas, in Case 2, a temperature of an upper surface is 361.62 degrees C., a temperature of a lower surface is 261.76 degrees C., and ΔT is 100 degrees C. From these results, it is confirmed that the heat shield member of the structure of the embodiment has a higher heat shield (insulation) effect. In addition, in Case 1, as shown in FIG. 9, cold spots exist around the support, and temperature uniformity within the surface is low, whereas, in Case 2, as shown in FIG. 10, such non-uniformity is not observed.

Although it is not physically possible, a similar simulation is performed on a case in which the supports are removed from Case 1. Resultantly, the temperature of the upper surface stays similar to that of Case 1, and ΔT becomes 89 degrees C. which is smaller than ΔT of Case 2. This is thought to be because Case 2 has connecting portions between the plates, and thus an area of the plate that contributes to heat shield in Case 2 is larger.

### OTHER APPLICATIONS

While the embodiment has been described hereinabove, it is to be noted that the embodiment disclosed herein is exemplary in all respects and is not restrictive. The above-described embodiment may be omitted, replaced, and/or modified in various forms without departing from the scope and spirit of the appended claims.

For example, while the above embodiment has exemplified a configuration in which the spiral portion as the heat shield member is sandwiched between the first flat plate and the second flat plate, the first flat plate and the second flat plate may not be required as long as the heat shield member has the spiral portion. The number of layers (number of windings) and pitch of the spiral portion and the thickness of the plate-like body are not limited to those in the above embodiment and may be appropriately set according to a required ΔT and a size of the chamber.

While the above embodiment has exemplified the case in which the heat shield member is applied to the film forming apparatus, the heat shield member is also applicable to a substrate processing apparatus that involves heating other than the film forming apparatus. Further, while the above embodiment has described an example in which the heat shield member is provided below the high-temperature heating type stage in the chamber to shield the radiant heat generated from the stage, the heat shield member is not limited thereto and may be used to shield radiant heat generated from a high-temperature member in the chamber. Furthermore, the heat shield member may be used not only to shield radiant heat, but also to shield (insulate) heat in order to suppress a temperature decrease caused by heat dissipation from members in the chamber. For example, the heat shield member may be disposed between the shower head 111 and a lid of the chamber 101 of the substrate processing apparatus of FIG. 5 to shield (insulate) heat therebetween and suppress a temperature decrease of the shower head 111.

Furthermore, while, in the above embodiment, an example in which the heat shield member is disposed in the chamber of the substrate processing apparatus has been shown, the heat shield member is not limited thereto and may be used for general heat shield (insulation) applications.

According to the present disclosure, a heat shield member capable of effectively shielding heat and a substrate processing apparatus using the same are provided.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A heat shield member for shielding heat, comprising:
a spiral portion formed by spirally winding a plate-like body to have a surface of the plate-like body overlapped at intervals in multiple layers.

2. The heat shield member of claim 1, further comprising a first flat plate and a second flat plate with the spiral portion interposed between the first flat plate and the second flat plate.

3. The heat shield member of claim 2, wherein the spiral portion, the first flat plate, and the second flat plate include metal materials.

4. The heat shield member of claim 3, wherein the spiral portion, the first flat plate, and the second flat plate include nickel or nickel alloys.

5. The heat shield member of claim 4, wherein the spiral portion is a body produced by additive manufacturing.

6. The heat shield member of claim 1, wherein the spiral portion is formed of a metal material, a ceramic material, or a composite material of metal and ceramic.

7. The heat shield member of claim 6, wherein the spiral portion is formed of nickel, a nickel alloy, zirconia, or a composite material of nickel and zirconia.

8. The heat shield member of claim 7, wherein the spiral portion is a body produced by additive manufacturing.

9. The heat shield member of claim 1, wherein the heat shield member is used to shield heat in a vacuum atmosphere.

10. The heat shield member of claim 9, wherein the spiral portion is a body produced by additive manufacturing.

11. The heat shield member of claim 1, wherein the spiral portion is a body produced by additive manufacturing.

12. A substrate processing apparatus for processing a substrate, comprising:
a processing container configured to accommodate the substrate and maintained in vacuum;
a member provided in the processing container; and
a heat shield member configured to shield heat generated from the member,
wherein the heat shield member includes a spiral portion formed by spirally winding a plate-like body to have a surface of the plate-like body overlapped at intervals in multiple layers.

13. The substrate processing apparatus of claim 12, wherein the member is a high-temperature member and the heat shield member shields radiant heat generated from the high-temperature member.

14. The substrate processing apparatus of claim 12, wherein the substrate processing apparatus is a film formation apparatus including, as the member, a high-temperature heating type stage configured to place the substrate and a shower head configured to supply a film forming gas inside the processing container, and
wherein the heat shield member is disposed below the stage and configured to shield radiant heat generated from the stage.

15. The substrate processing apparatus of claim 12, wherein the substrate processing apparatus is a film formation apparatus including, as the member, a high-temperature heating type stage configured to place the substrate and a shower head configured to supply a film forming gas inside the processing container, and
wherein the heat shield member is provided between the processing container and the shower head to suppress a temperature of the shower head from being lowered.
